(19) United States
(12) Patent Application Publication
(10) Pub. No.: US 2007/0131940 A1
(43) Pub. Date: Jun. 14, 2007

(54) Color-mixing LED

(75) Inventors: Tung-Ching Wu, San Chung City (TW); Ching-Huei Wu, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/296,498

(22) Filed: Dec. 8, 2005

(51) Int. Cl. H01L 33/00; H01L 31/12; H01L 27/15; H01L 29/26

(52) U.S. Cl. 257/79

(57) ABSTRACT

A color-mixing LED is disclosed. Fluorescent powders are mixed with an adhesive to form a thin plate. A segmentation process is then performed on the thin plate. A chip is coupled to a concave bracing frame, and then the segmented thin plate is mounted in the concave bracing frame against its inner walls. A transparent adhesive for fixing is injected into the concave bracing frame, whereby the color-mixing LED has simplified manufacturing procedure, reduced manufacturing cost, and easy assembling design.

### FIELD OF THE INVENTION

The present invention relates a light emitting diode (LED) or the like, and more particularly to a color-mixing LED that has simplified manufacturing procedure, effective reduced manufacturing cost, and easy assembling design.

### BACKGROUND OF THE INVENTION

The LED, which is previously applied to indicators of electronic products in early years, provides the advantages of lower power consumption, long lifetime, and producing no heat, so it is currently further applied to lighting and large-sized display screen. However, the generation of white light from the LED is an important key technology when the LED is applied to the lighting.

In order to obtain the white light by mixing primary colors with one another, different chips for respectively emitting red, green, and blue lights must be applied simultaneously since most common LEDs generate colored lights, for example, red light, green light, blue light, etc. As a result, the white light can be obtained by exciting these chips with different current values. Referring to FIG. 4, a conventional white light LED is shown, wherein red, blue, and green-light chips A1, A2, and A3 are packaged in a package C. Besides, a control chip E is also packaged in this package C. The chips A1, A2, and A3 are connected to the control chip E by bonding wires B, wherein they are connected to the outside environment by pins D.

However, in this conventional structure, these chips are mounted separately. In other words, the white light is only generated on optical overlaps of these three chips. The light, which is generated on the edge of every chip, has the same color as the light emitted from this chip, and the light, which is generated on the optical overlaps of every two chips, is a mixing light of these two chips. As a result, its manufacturing cost is increased and its manufacturing procedure is more complicated since there is a need to mount another control chip.

In view of the aforementioned conventional deficiencies, the present inventor makes diligent studies in providing consumers with a color-mixing LED that has simplified manufacturing procedure, effective reduced manufacturing cost, and easy assembling design according to the motive of the present invention.

### SUMMARY OF THE INVENTION

It is a main objective of the present invention to provide a color-mixing LED with simplified manufacturing procedure, effective reduced manufacturing cost, and easy assembling design.

In order to achieve this objective, fluorescent powders are mixed with an adhesive to form a thin plate. A segmentation process is then performed on the thin plate. A chip is coupled to a concave bracing frame, and then the segmented thin plate is mounted in the concave bracing frame against its inner walls. A transparent adhesive for fixing is injected into the concave bracing frame. Accordingly, the color-mixing LED has simplified manufacturing procedure, reduced manufacturing cost, and easy assembling design.

The aforementioned objectives and advantages of the present invention will be readily clarified in the description of the preferred embodiments and the enclosed drawings of the present invention.

### BRIEF DESCRIPTION OF THE DRAWINGS

FIG. 1 is a schematic, assembled view showing a first preferred embodiment of the present invention.

FIG. 2 is a schematic, assembled view showing a second preferred embodiment of the present invention.

FIG. 3 is a schematic, assembled view showing a third preferred embodiment of the present invention.

FIG. 4 is a top view showing a conventional white-light LED.

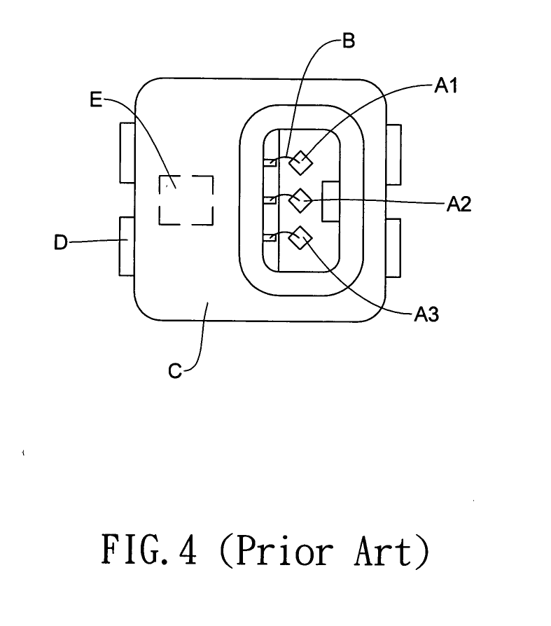

### DETAILED DESCRIPTION OF THE PREFERRED EMBODIMENT

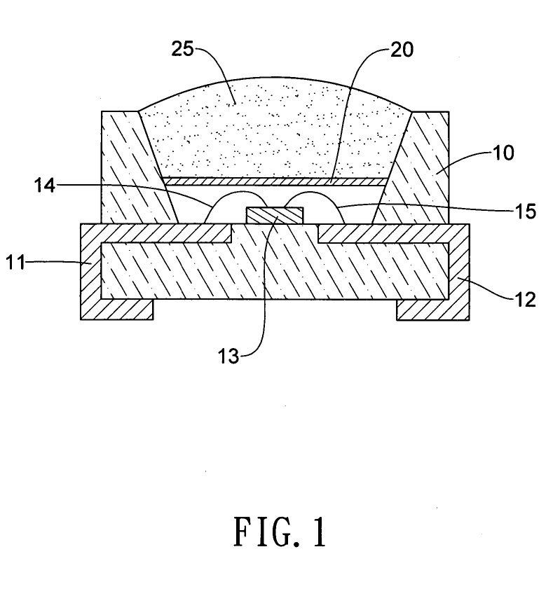

As shown FIG. 1, according to a preferred embodiment of the present invention, two opposite-polarity pins 11, 12 are mounted on bottom edges of a concave bracing frame 10, wherein a chip 13 is coupled to the inside of the concave bracing frame 10, and the chip 13 is connected to the opposite-polarity pins 11, 12 via two bonding wires 14, 15. At least a thin plate 20 is mounted above these two bonding wires 14, 15. The thin plate 20 is made of a mixture of fluorescent powders and an adhesive, and it is manufactured by injection molding or casting method, wherein the adhesive is, for example, epoxy resin, polyphthalamide (abbreviated as PPA), or silicon gel. Thereafter, a segmentation process is performed to segment the manufactured thin plate 20 into proper-sized pieces, and the segmented thin plate 20 is then mounted inside the concave bracing frame 10 against its inner walls so as to separate the chip 13 and the bonding wires 14, 15 from the outside environment. Thereafter, the bracing frame 10 is covered with a transparent adhesive 25 for the purpose of fixing, wherein the transparent adhesive 25 is, for example, epoxy resin, polyphthalamide (abbreviated as PPA), or silicon gel such that the thin plate 20 is steadily mounted inside the concave bracing frame 10 for separating the transparent adhesive 25 from the chip 13 and that the amount of the transparent adhesive 25, which is used in the manufacture of the light emitting diode, can be reduced effectively.

After the manufactured light emitting diode is supplied with electric power, the colored light emitted from the chip 13 will pass through the thin plate 20 that contains uniform fluorescent powders. A uniform mixing light with no chromatic aberration is formed when the thin plate 20 is excited by the colored light since the thin plate 20 has a uniform thickness and the fluorescent powders dissolved in the thin plate 20 has a uniform density.

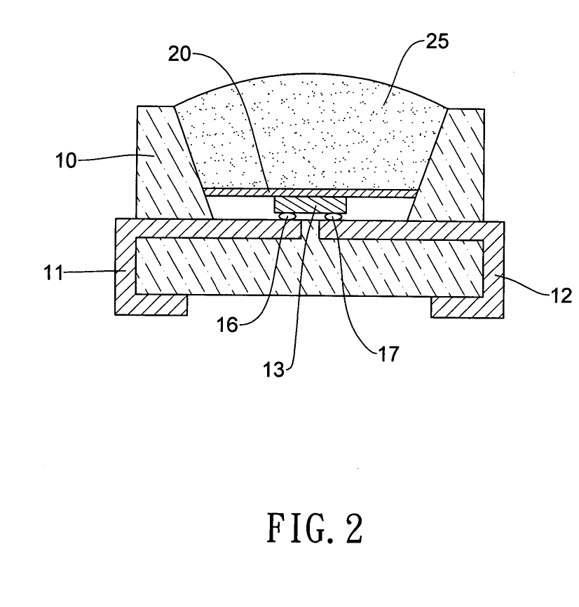

Referring further to FIG. 2, the chip 13 can be flip-chip bonded to the opposite-polarity pins 11, 12 by tin solders or gold solders. The tin solders 16, 17 are exemplified in this second preferred embodiment. The chip 13 is flip-chip bonded to the opposite-polarity pins 11, 12 by the tin solders 16, 17, and the thin plate 20 is stacked over the chip 13. There is no need to utilize the bonding wires since the chip 13 is flip-chip bonded to the opposite-polarity pins 11, 12 directly. As a result, the thin plate 20 can be stacked on the chip 13 directly or mounted above the chip 13.

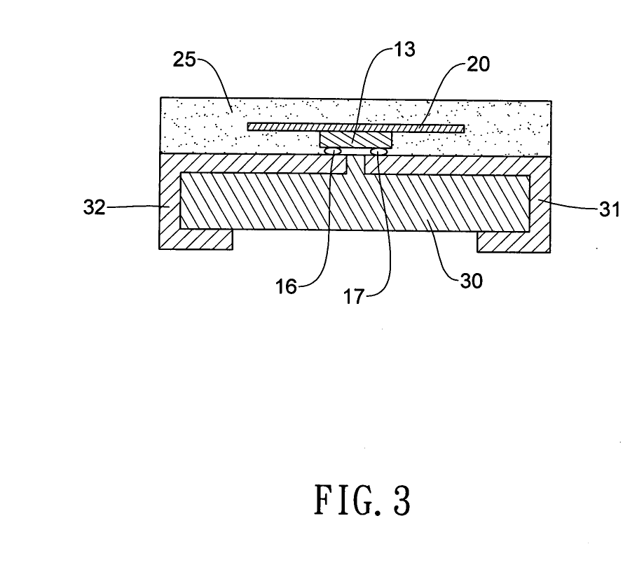

Referring further to FIG. 3, the bracing frame can be replaced by a printed circuit board (PCB) 30 or a ceramic board, wherein two electrodes 31, 32 are mounted on the PCB 30, and the chip 13 is flip-chip bonded to the electrodes 31, 32 by tin solders 16, 17. The segmented thin plate 20 is mounted on the chip 13, and the thin plate 20 and the chip 13 are thereafter packaged by the transparent adhesive 25 for fixing so as to complete the manufacture of the light emitting diode.

According to the foregoing description, it is apparent that the structure of the present invention provides the following advantages, wherein:

1. By use of the thin plate that has the fluorescent powders, the manufacturing procedure of the color-mixing LED can be simplified effectively such that its assembly is easy so as to reduce the manufacturing cost effectively.

2. The thin plate that mounts above the chip has a uniform thickness and uniform fluorescent powders so as to produce uniform mixing light.

3. The concave bracing frame is partitioned into two parts by the thin plate such that the transparent adhesive only covers the space over the thin plate and not covers the space under the thin plate so as to reduce the required amount of the transparent adhesive.

In summary, the color-mixing LED disclosed in the present invention satisfies patentability. Accordingly, it is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A color-mixing LED comprising:
a thin plate, the thin plate being a mixture of fluorescent powders and an adhesive;
a concave bracing frame, the thin plate being segmented and mounted in the concave bracing frame against inner walls of the concave bracing frame;
a chip coupled to the inside of the concave bracing frame; and
a transparent adhesive injected into the concave bracing frame for fixing, whereby the color-mixing LED has simplified manufacturing procedure, reduced manufacturing cost, and easy assembling design.

2. The color-mixing LED of claim 1, wherein the adhesive of the thin plate is epoxy resin, polyphthalamide (PPA), or silicon gel.

3. The color-mixing LED of claim 1, wherein the chip is wire-bonded and connected to the concave bracing frame by bonding wires and the thin plate that locates against the concave bracing frame is higher than the bonding wires.

4. The color-mixing LED of claim 1, wherein the chip is flip-chip bonded to the concave bracing frame and the thin plate is mounted over the chip.

5. The color-mixing LED of claim 1, wherein the transparent adhesive is epoxy resin, polyphthalamide (PPA), or silicon gel.

6. A color-mixing LED comprising:
a printed circuit board on which at least two electrodes are mounted;
a chip coupled to the electrodes;
a thin plate mounted on the chip, the thin plate being made of a mixture of fluorescent powders and an adhesive; and
a transparent adhesive for fixing the thin plate over the chip mounted on the printed circuit board, whereby the color-mixing LED has simplified manufacturing procedure, reduced manufacturing cost, and easy assembling design.

7. The color-mixing LED of claim 6, wherein the adhesive of the thin plate is epoxy resin, polyphthalamide (PPA), or silicon gel.

8. The color-mixing LED of claim 6, wherein the transparent adhesive is epoxy resin, polyphthalamide (PPA), or silicon gel.

9. A color-mixing LED comprising:
a ceramic board on which at least two electrodes are mounted;
a chip coupled to the electrodes;
a thin plate mounted on the chip, the thin plate being made of a mixture of fluorescent powders and an adhesive; and
a transparent adhesive for fixing the thin plate over the chip mounted on the ceramic board, whereby the color-mixing LED has simplified manufacturing procedure, reduced manufacturing cost, and easy assembling design.

10. The color-mixing LED of claim 9, wherein the adhesive of the thin plate is epoxy resin, polyphthalamide (PPA), or silicon gel.

11. The color-mixing LED of claim 9, wherein the transparent adhesive is epoxy resin, polyphthalamide (PPA), or silicon gel.
